(19) United States
(12) Patent Application Publication
(10) Pub. No.: US 2025/0077719 A1
(43) Pub. Date: Mar. 6, 2025

(54) PARAMETER OPTIMIZATION DEVICE AND PARAMETER OPTIMIZATION METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiro GANGI, Tokyo (JP); Yasunori TAGUCHI, Kawasaki (JP); Tomoaki INOKUCHI, Yokohama (JP); Yusuke KOBAYASHI, Yokohama (JP); Taichi FUKUDA, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/585,541

(22) Filed: Feb. 23, 2024

(30) Foreign Application Priority Data
Sep. 1, 2023 (JP) 2023-142354

(51) Int. Cl. G06F 30/12

(52) U.S. Cl. CPC G06F 30/12

(57) ABSTRACT

A parameter optimization device includes a processing device configured to: generate a partial search space of a second dimensionality from a search space of a first dimensionality, the second dimensionality being less than the first dimensionality; select a plurality of search points in the partial search space by correcting an acquisition function with a local penalty function; and observe, in parallel, a plurality of objective functions corresponding respectively to the plurality of search points.

### CROSS-REFERENCE TO RELATED APPLICATION

This application is based upon and claims the benefit of priority from Japanese Patent Application No. 2023-142354, filed on Sep. 1, 2023; the entire contents of which are incorporated herein by reference.

### FIELD

Embodiments described herein relate generally to a parameter optimization device and a parameter optimization method.

### BACKGROUND

There is a need for a technique to efficiently solve an optimization problem that has many parameters and requires much time for one evaluation. For example, in the design of a power semiconductor element, there are several to several tens of parameters, and one evaluation (simulator run) may take several hours.

### BRIEF DESCRIPTION OF THE DRAWINGS

FIG. 1 is a schematic view showing a configuration of a parameter optimization device of an embodiment;

FIG. 2 is a flowchart of a parameter optimization method of the embodiment;

FIG. 3 is a schematic view showing an example of a partial search space; and

FIG. 4 is a graph showing results of examples of the parameter optimization method of the embodiment.

### DETAILED DESCRIPTION

According to one embodiment, a parameter optimization device includes a processing device configured to: generate a partial search space of a second dimensionality from a search space of a first dimensionality, the second dimensionality being less than the first dimensionality; select a plurality of search points in the partial search space by correcting an acquisition function with a local penalty function; and observe, in parallel, a plurality of objective functions corresponding respectively to the plurality of search points.

Embodiments will now be described with reference to the drawings.

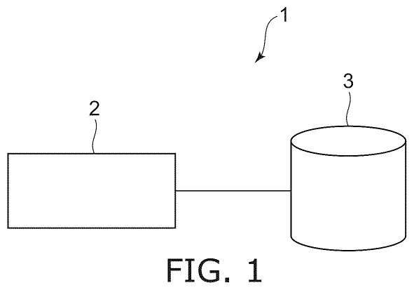

As shown in FIG. 1, a parameter optimization device 1 of an embodiment includes a processing device 2 and a storage device 3. Input data such as parameters and the like input to the processing device 2, output data such as calculated values of the processing device 2, etc., can be stored in the storage device 3. The processing device 2 can include, for example, multiple simulators of TCAD (Technology Computer Aided Design) and the like, and a host computer electrically connected with the multiple simulators. A program that causes the processing device 2 to perform a parameter optimization method is recorded in the desired recording medium in a form that is readable by the processing device 2. The recording medium may be, for example, a recording device 3. The program includes steps S1 to S10 described below.

For example, the parameter optimization device 1 of the embodiment can use Bayesian optimization to optimize design variables (parameters) of a power semiconductor element. For example, the parameters of the power semiconductor element include electrical characteristics such as the on-resistance, breakdown voltage, etc. Optimization of the design variables (parameters) means to search for design variables (parameters) for which the value of an objective function is less than a target value, not more than the target value, greater than the target value, or not less than the target value.

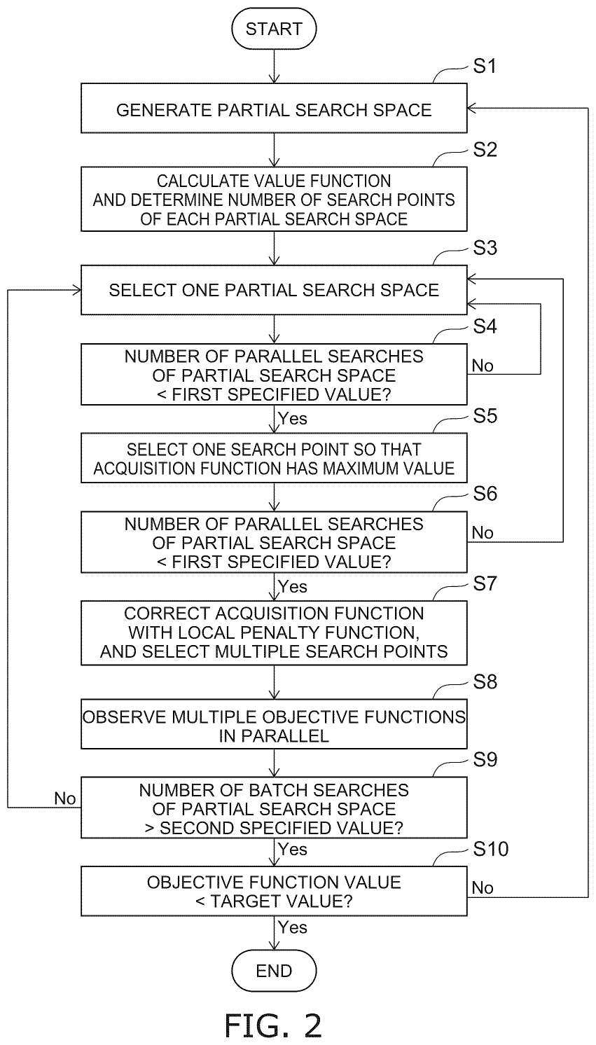

The parameter optimization device 1 of the embodiment can perform processing described below with reference to FIG. 2.

As step S1, a partial search space of a second dimensionality is generated from a search space of a first dimensionality; and the second dimensionality is less than the first dimensionality.

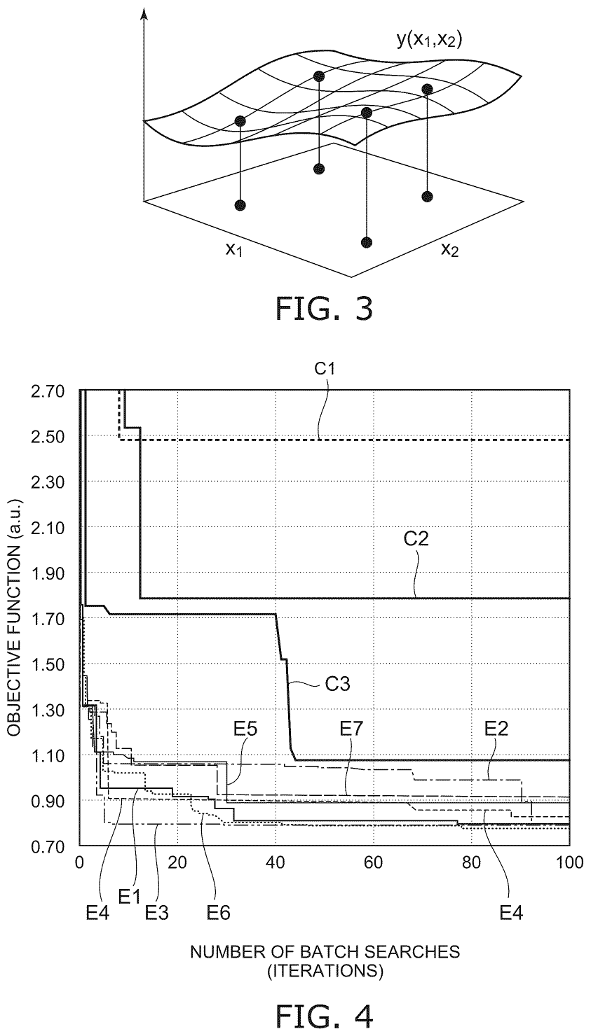

The search space of an objective function y(x₁, . . . , x_{D}) including D parameters is defined in D-dimensional space. For example, for a semiconductor element, a partial search space of two dimensions, as a second dimensionality, is generated from a search space of six dimensions, as a first dimensionality. FIG. 3 shows an example of a partial search space of the objective function y(x₁, x₂) defined in two-dimensional space. For example, multiple partial search spaces are generated so that each includes the current optimal search points. The current optimal search points are design values in search history data that reduce the objective function the most.

In the next step S2, a value function of the multiple partial search spaces is calculated, and a number of search points for observing the objective functions in parallel is determined for each of the multiple partial search spaces based on the value function.

The value function represents the search value of the partial search space. The total number of parallel searches is allocated to the multiple partial search spaces based on the value function. For example, a user can determine the total number of parallel searches according to the number of simulators that can be utilized in the parallel search (the simultaneous observation of the objective functions).

For example, the value function can be calculated based on the maximum value of the acquisition function. For example, the acquisition function is calculated by combining the variance (the standard deviation) and the expected value of the objective function estimated by a Gaussian process regression. For example, LCB (Lower Confidence Boundary), EI (Expected Improvement), etc., can be used as the acquisition function.

For example, eleven partial search spaces, i.e., first to eleventh partial search spaces, are generated. The number of search points is determined for each of the first to eleventh partial search spaces based on the maximum value of the acquisition function of each of the first to eleventh partial search spaces. For example, search priority ranks can be assigned to the first to eleventh partial search spaces in descending order of the maximum value of the acquisition function; and more search points can be distributed to partial search spaces having high search priority ranks than partial search spaces having low search priority ranks. One partial search space has more search points than another partial search space. Another partial search space that has a larger maximum value of the acquisition function than one partial search space has more search points than the one partial search space.

For example, the total number of parallel searches is taken to be 10.

As a first example, the number of search points of the first partial search space can be set to 10; and the number of search points can be set to 0 for each of the second to eleventh partial search spaces. The total number of parallel searches can be allocated to the partial search space having the highest search priority rank. The number of search points can be set to 0 for the remaining partial search spaces.

As a second example, the number of search points can be set to 1 for each of the first to tenth partial search spaces; and the number of search points can be set to 0 for the eleventh partial search space. The number of parallel searches can be allocated one at a time to the partial search spaces in order from the higher search priority ranks. The same number of parallel searches can be allocated respectively to the partial search spaces in order from the higher search priority ranks. The number of search points can be set to 0 for the remaining partial search spaces.

As a third example, the number of search points can be set to 4 for the first partial search space; the number of search points can be set to 3 for the second partial search space; the number of search points can be set to 2 for the third partial search space; the number of search points can be set to 1 for the fourth partial search space; and the number of search points can be set to 0 for each of the fifth to eleventh partial search spaces. The same number of parallel searches or more parallel searches can be allocated to partial search spaces having higher search priority ranks than partial search spaces having lower search priority ranks. The number of search points can be set to 0 for the remaining partial search spaces.

As a fourth example, the number of search points can be set to 5 for the first partial search space; the number of search points can be set to 1 for each of the second to sixth partial search spaces; and the number of search points can be set to 0 for each of the seventh to eleventh partial search spaces. The same number of parallel searches can be allocated in order from the higher search priority ranks. A greater number of parallel searches can be allocated to the partial search space having the highest search priority rank than the partial search spaces having the second and lower search priority ranks.

As a fifth example, the number of search points can be set to 3 for each of the first to third partial search spaces; the number of search points can be set to 1 for the fourth partial search space; and the number of search points can be set to 0 for each of the fifth to eleventh partial search spaces. Any number of parallel searches (e.g., 3) can be allocated to partial search spaces having higher search priority ranks. The remaining number of parallel searches can be allocated to the remaining partial search spaces having higher search priority ranks. The number of search points can be set to 0 for the rest of the partial search spaces.

The method for allocating the search points to the partial search spaces can be modified each time the number of batch searches exceeds a prescribed number. The method for allocating the search points to the partial search spaces can be modified each time a batch search of the same objective function value is repeated a prescribed number of times. The number of search points of one partial search space may be different between one batch search and another batch search.

Or, the value function may be calculated based on the absolute value of a coefficient of a polynomial regression equation of the objective function. The search priority ranks can be assigned to the first to eleventh partial search spaces in descending order of absolute value of the coefficient of the polynomial regression equation of the objective function. More search points can be distributed to partial search spaces having high search priority ranks than partial search spaces having low search priority ranks.

Or, the value function may be calculated based on the maximum value of the variance of the objective function. The search priority ranks can be assigned to the first to eleventh partial search spaces in descending order of maximum value of the variance of the objective function; and more search points can be distributed to partial search spaces having high search priority ranks than partial search spaces having low search priority ranks.

The value function is not limited to one value function; and the number of search points may be determined based on multiple value functions. Search points can be allocated for each value function. The number of searches also can be allocated by generating a composite function of multiple value functions.

In the next step S3, one partial search space is selected from the multiple partial search spaces. For example, one partial search space is selected randomly from the multiple partial search spaces.

In the next step S4, the number of parallel searches of the partial search space selected in step S3 is compared with a first specified value. When the number of parallel searches of the selected partial search space is less than the first specified value, the flow proceeds to the next step S5.

When the number of parallel searches of the selected partial search space is not less than the first specified value, the flow returns to step S3 without further searches of the partial search spaces; and new partial search spaces are regenerated. As a result, a specific partial search space can be prevented from being continuously searched a number of times not less than the first specified value. For example, the first specified value can be set to a number N estimated to be such that the objective function would not improve when continuously searching the partial search space N or more times. For example, the first specified value can be set to the partial search space dimension D×5, the partial search space dimension D×10, etc. It is favorable for the first specified value to be large when the partial search space dimension is high or the search range is wide.

In the next step S5, one search point is selected in the selected partial search space so that the acquisition function has a maximum value.

In the next step S6, processing similar to step S4 described above is performed. When step S6 is Yes, the flow proceeds to step S7.

In step S7, multiple search points of the partial search space are selected by correcting the acquisition function with a local penalty function. For a continuous acquisition function, multiple discrete search points are selected by sequentially multiplying the acquisition function by local penalty functions ϕ₁, ϕ₂, . . . . For example, a first search point can be selected at which the acquisition function before the local penalization has a maximum value; the acquisition function can be corrected by multiplying the acquisition function of the proposed first search point by the local penalty function ϕ₁; a second search point can be selected so that the corrected acquisition function has a maximum value; the acquisition function can be corrected by multiplying the acquisition function of the proposed second search point by the local penalty function ϕ₂; and a third search point can be selected so that the corrected acquisition function has a maximum value. The number of search points is determined based on the value function described above.

In the next step S8, multiple objective functions that correspond respectively to the multiple search points are observed in parallel. For each objective function, the variance and the expected value estimated based on the Gaussian process regression are updated; and the acquisition function is updated.

In the next step S9, the number of batch searches of the partial search spaces and a second specified value are compared. The series of processing from step S3 to step S8 is taken to be one batch search.

When the number of batch searches is not more than the second specified value, the flow returns to step S3; and new partial search spaces are regenerated.

When the number of batch searches is greater than the second specified value, the flow proceeds to step S10. In step S10, a target value and the value of the objective function obtained by the processing up to step S9 are compared. In the example, when the objective function is less than the target value, the parameter optimization device 1 proposes optimal design values of the design variables (parameters), and ends the processing.

When the objective function is not less than the target value, the flow returns to step S1; and the multiple partial search spaces are regenerated.

According to the embodiment, many parameters can be optimized in a short period of time by selecting multiple search points in partial search spaces having few dimensions, and by observing multiple objective functions in parallel. Also, the multiple partial search spaces are ranked based on the value function; and the number of searches are allocated according to the rank. As a result, the search can be performed by weighting partial search spaces that seem to have high search values; and optimization is possible in a shorter period of time.

FIG. 4 is a graph showing results of the examples of the parameter optimization method of the embodiment.

In step S1 described above, a partial search space having two dimensions, as the second dimensionality, was generated from a search space having six dimensions, as the first dimensionality, for a power MOSFET (Metal-Oxide-Semiconductor Field Effect Transistor) having a field plate structure. The directions of two basis vectors of the two-dimensional partial search space were random. Eleven partial search spaces, i.e., the first to eleventh partial search spaces, were generated.

As the objective function,

$$Y = RonA / 30 + 10 \times Re LU ( 110 - Vdss ) \qquad ( 1 )$$

was used. The parameters were an on-resistance RonA and a breakdown voltage Vdss. ReLU was a normalized linear function such that ReLU (110−Vdss) was 0 when the breakdown voltage Vdss was not less than 110 V. The objective function (1) was a formula that minimized the on-resistance under the constraint of the breakdown voltage being not less than 110 V.

The initial search point of the on-resistance RonA was set to 75 mΩmm²; and the initial search point of the breakdown voltage Vdss was set to 79 V.

The total number of parallel searches was set to 10. The value function was calculated based on the maximum value of the acquisition function of each partial search space. In FIGS. 4, E1, E2, E3, E4, and E5 respectively represent the allocations of the number of searches according to the first example, the second example, the third example, the fourth example, and the fifth example described above.

In the sixth example E6, the first to fifth examples were randomly selected each time the partial search spaces were regenerated.

In the seventh example E7, the number of search points distributed to the ith partial search space was proportional to a maximum value α_{max,i} of the acquisition function. In other words, the number of search points of the ith partial search space was the total number of parallel searches 10×α_{max,i}/(Σᵢα_{max,i}).

C1 represents a first comparative example in which the six-dimensional search space of the MOSFET described above was searched without a parallel search.

C2 represents a second comparative example in which the six-dimensional search space of the MOSFET described above was searched in parallel. The number of parallel searches was 10.

C3 represents a third comparative example in which the two-dimensional partial search space of the MOSFET described above was searched without a parallel search.

FIG. 4 shows an example in which the batch search was performed 100 times. In the first and third comparative examples C1 and C3 without parallel searches, the total number of searches was 100. In the second comparative example C2 and the first to seventh examples E1 to E7 in which the number of parallel searches was 10, the total number of searches was number of parallel searches 10×number of batch searches 100=1,000. The number of batch searches corresponds to time; and the design can be completed in a short period of time as the number of batch searches decreases.

From the results of FIG. 4, at the completion of one hundred batch searches, the first to seventh examples E1 to E7 searched for the parameters to minimize the objective function (1) better than the first to third comparative examples C1 to C3. The target value of the objective function was, for example, 1. The first to seventh examples E1 to E7 searched for the parameters to minimize the objective function (1) of fewer batch iterations than the first to third comparative examples C1 to C3.

In particular, the parameters obtaining the smallest objective function were searched by the sixth example E6 in which the first to fifth examples were randomly selected each time the partial search spaces were regenerated.

The value function may be modified each time the partial search spaces are regenerated.

The user inputs a search lower limit and a search upper limit to the processing device 2 for each parameter. The search space of the first dimensionality is specified and generated according to the input values. The user may input at least one design value as an initial search point to be included in the search space of the first dimensionality. When there is one initial search point, the processing shown in FIG. 2 above is performed by considering the initial search point to be an optimal search point. The user may input multiple initial search points. When there are multiple initial search points, the processing shown in FIG. 2 above is performed by considering the search points among the initial search points that minimize the objective function to be optimal search points. For example, the multiple initial search points can be randomly generated. Or, the multiple initial search points can be searched using a normal Bayesian optimization.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A parameter optimization device, comprising:
a processing device configured to:
generate a partial search space of a second dimensionality from a search space of a first dimensionality, the second dimensionality being less than the first dimensionality;
select a plurality of search points in the partial search space by correcting an acquisition function with a local penalty function; and
observe, in parallel, a plurality of objective functions corresponding respectively to the plurality of search points.

2. The parameter optimization device according to claim 1, wherein
a value function of a plurality of the partial search spaces is calculated, and
a number of the search points for observing the objective functions in parallel is determined for each of the plurality of partial search spaces based on the value function.

3. The parameter optimization device according to claim 2, wherein
the value function is calculated based on a maximum value of the acquisition function.

4. The parameter optimization device according to claim 2, wherein
the value function is calculated based on an absolute value of a coefficient of a polynomial regression equation of the objective function.

5. The parameter optimization device according to claim 2, wherein
the value function is calculated based on a maximum value of a variance of the objective function.

6. The parameter optimization device according to claim 2, wherein
the number of the search points is determined based on a plurality of the value functions.

7. The parameter optimization device according to claim 6, wherein
the value function is modified each time the partial search spaces are regenerated.

8. The parameter optimization device according to claim 1, wherein
a plurality of initial search points is generated.

9. The parameter optimization device according to claim 2, wherein
the plurality of partial search spaces includes at least:
a first partial search space;
a second partial search space, the second partial search space having a larger maximum value of the acquisition function than the first partial search space, and
the second partial search space has more search points than the first partial search space.

10. The parameter optimization device according to claim 2, wherein
the number of the search points of at least one of the partial search spaces is different between one batch search and another batch search.

11. A parameter optimization method, comprising:
generating search space of a second dimensionality from a search space of a first dimensionality, the second dimensionality being less than the first dimensionality;
selecting a plurality of search points in the partial search space by correcting an acquisition function with a local penalty function; and
observing, in parallel, a plurality of objective functions corresponding respectively to the plurality of search points.

12. The method according to claim 11, wherein
a value function of a plurality of the partial search spaces is calculated, and
a number of the search points for observing the objective functions in parallel is determined for each of the plurality of partial search spaces based on the value function.

13. The method according to claim 12, wherein
the value function is calculated based on a maximum value of the acquisition function.

14. The method according to claim 12, wherein
the value function is calculated based on an absolute value of a coefficient of a polynomial regression equation of the objective function.

15. The method according to claim 12, wherein
the value function is calculated based on a maximum value of a variance of the objective function.

16. The method according to claim 12, wherein
the number of the search points is determined based on a plurality of the value functions.

17. The method according to claim 12, wherein
the value function is modified each time the partial search spaces are regenerated.

18. The method according to claim 11, wherein
a plurality of initial search points is generated.
